(19) United States
(12) Patent Application Publication
(10) Pub. No.: US 2025/0081330 A1
(43) Pub. Date: Mar. 6, 2025

(54) Component Carrier with Rough Surface and Smooth Surface Metal Traces and Manufacturing Method

(71) Applicant: AT&S Austria Technologie & Systemtechnik AG, Leoben (AT)

(72) Inventors: Patrick LENHARDT, Spielberg (AT); Jeesoo MOK, Chongqing (CN); Minwoo LEE, Chongqing (CN); Hans PARK, Chongqing (CN); Artan BAFTIRI, Congqing (CN)

(21) Appl. No.: 18/693,630

(22) PCT Filed: Apr. 25, 2023
(86) PCT No.: PCT/EP2023/060721

§ 371 Date: Mar. 20, 2024

(30) Foreign Application Priority Data
Apr. 28, 2022 (CN) 202210470213.5

(51) Int. Cl. H05K 1/02; H05K 3/00; H05K 3/10; H05K 3/28

(52) U.S. Cl. CPC H05K 1/0237; H05K 3/0017; H05K 3/10; H05K 3/28

(57) ABSTRACT

A component carrier including: i) a stack with at least one electrically insulating layer structure and at least one electrically conductive layer structure; ii) a first metal trace comprising a rough surface; and iii) a second metal trace arranged adjacent to the first metal trace, comprising a smooth surface. The component carrier is configured to guide high-frequency and or high-speed signals through the second metal trace.

### CROSS-REFERENCE TO RELATED APPLICATIONS

This application is a national stage application, filed under 35 U.S.C. § 371, of International Patent Application No. PCT/EP2023/060721, filed on Apr. 25, 2023, claiming priority of the Chinese Patent Application No. CN 202210470213.5, filed on Apr. 28, 2022, the disclosures of which are hereby incorporated by reference herein in their entirety.

### TECHNICAL FIELD

The disclosure relates to a component carrier such as a printed circuit board or a circuit substrate and to a method of manufacturing the component carrier.

### TECHNOLOGICAL BACKGROUND

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. Also, an efficient protection against electromagnetic interference (EMI) is becoming an increasing issue. At the same time, component carriers shall be mechanically robust and electrically and magnetically reliable so as to be operable even under harsh conditions.

In particular, providing a reliable signal transmission (even in the high-frequency range) and at the same time a stable architecture may be considered a challenge. The adhesion between metallic structures and dielectric materials of a component carrier is generally poor, thereby potentially causing drawbacks regarding stability of the component carrier, e.g. issues by delamination.

Conventionally, surface roughening of the metal structure may be widely used in the component carrier industry to improve the adhesion between metal (e.g. copper) and the dielectric material (such as e.g. FR4, ABF, PID, or solder resist) due to the higher roughness. A high roughness on the metal surface may lead to better adhesion of the dielectric material but may have at the same time the disadvantage that the high roughness, e.g. due to the skin effect, leads to signal losses, especially in the high-frequency range. Furthermore, less rough (oxide-free) metallic surfaces may be advantageous for specific manufacturing processes, e.g. sintering.

### SUMMARY

There may be a need to provide a component carrier with a reliable signal transmission (in particular regarding high frequencies) and a robust design.

A component carrier, a manufacturing method, and a method of using are provided.

According to an aspect of the disclosure, there is described a component carrier, comprising: i) a stack comprising at least one electrically insulating layer structure and at least one electrically conductive layer structure; ii) a first metal trace comprising a rough surface; and iii) a second metal trace arranged adjacent (i.e. close to each other, with no other metal trace in between, physical contact possible, but not mandatory) to the first metal trace, comprising a smooth surface. In particular, the component carrier is configured to guide high-frequency (HF) signals and/or high-speed signals (only) through the second metal trace.

According to a further aspect of the disclosure, there is described a method of manufacturing a component carrier, the method comprising: i) forming a stack comprising at least one electrically insulating layer structure and/or at least one electrically conductive layer structure; ii) forming a first metal trace with a rough surface; iii) forming a second metal trace, adjacent to the first metal trace, with a smooth surface; and iv) configuring the component carrier, so that high-frequency, HF, signals and/or high speed signals can be guided through the second metal trace.

According to a further aspect of the disclosure, there is described a use (method of using) of a smooth-surface metal trace, arranged adjacent to a rough-surface metal trace, for guiding signals with a frequency of at least 6 GHz in and/or on a component carrier (while these high-frequency signals are not guided via the first metal trace or whereby more high-frequency signals are guided via the second metal trace than via the first metal trace.

### Overview of Embodiments

In the context of the present document, the term “metal trace” may refer to an electrically conductive structure that comprises a metal, in particular copper. In particular, a metal trace may be configured as an elongated (preferably in the horizontal direction) electrically conductive structure that may serve for the transmission of signals, in particular high frequency signals and/or high-speed signals. Additionally or alternatively, the metal trace may conduct electric current, in particular current in the range of 1 pA-1000 A. Further, a metal trace with a rough surface may establish an adhesion with dielectric material, thereby enhancing the stability of a component carrier. A metal trace (with a rough surface) may have for example a shape of an elongated trace, an annular ring or may be configured as a pad or block.

In the context of the present document, the term “surface roughness” may in particular refer to a property of a metal trace surface, e.g. a sidewall portion property and/or a top portion property. The surface roughness may be seen as a relative term, for example the roughness of a first metal trace is high in comparison to the surface roughness of a second metal trace with a lower roughness. In a further example, surface roughness may be seen as an absolute term, e.g. given as Ra. In a specific example, a rough surface may comprise a surface roughness Ra of more than 500 nm, in particular more than 700 nm. In a further specific example, the smooth surface may comprise a surface roughness Ra of less than 500 nm, in particular less than 300 nm, more in particular less than 100 nm.

In the context of the present document, the term “adjacent” (or side-by-side) may in particular refer to the circumstance that a first metal trace and a second metal trace (as described above) are arranged next to each other. In particular, there may be no further metal trace arranged in between. In an example, the first metal trace and the second metal trace may be in direct (physical) contact with each other. In another example, the first metal trace and the second metal trace may be arranged close to each other, but not in direct (physical) contact. In particular, the first metal trace and the second metal trace may be arranged on the same vertical height on a common dielectric substrate. In another example, the first metal trace and the second metal trace may be arranged next to each other but on different vertical heights and/or on different substrates. Along the length of the (elongated) metal traces they may be arranged in parallel, at least partially in parallel, or not in parallel with each other.

In the context of the present document, the term “high speed” may refer to digital technology which transmits data at a very high rate (related to time domain). In the context of the present document, the term “high frequency” may in particular refer to the radio frequency of an analog signal at high frequency moving energy (which is related to how electromagnetic wave respond in a specific frequency or range of frequency). However, there may also be a fundamental relationship between high speed (digital) signals and high frequency techniques. For example, pulses for digital information transmission are generated by RF waveforms. Basically, a sine wave can be thought of as an RF waveform. When several sine waves of different frequencies are combined, they can form a square wave, and a square wave can generate a pulse of a digital signal. As a simple example, the 2 GB/s digital pulse speed (clock speed) is formed by RF signals at frequency of about 1 GHz, 3 GHz, 5 GHz, 7 GHz, etc., sorted by a given frequency, respectively, at the fundamental frequency (1 GHz), the fundamental frequency three times harmonic (3 GHz), five times harmonic (5 GHz) and seven times harmonic (7 GHz) frequency.

In the context of the present document, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, a metal core substrate, an inorganic substrate and an IC (integrated circuit) substrate. A component carrier may also be a hybrid board combining different ones of the above-mentioned types of component carriers.

In the present context, the term “component carrier” may refer to a final component carrier product as well as to a component carrier preform (i.e. a component carrier in production, in other words a semi-finished product). In an example, a component carrier preform may be a panel that comprises a plurality of semi-finished component carriers that are manufactured together. At a final stage, the panel may be separated into the plurality of final component carrier products.

According to an exemplary embodiment, the disclosure may be based on the idea that a component carrier with a reliable signal transmission (in particular regarding high frequencies and/or high speed) and a robust design may be provided, when a first metal trace of the component carrier is provided with a rough surface and when a second metal trace of the component carrier is provided with a smooth surface. The first metal trace and the second metal trace are preferably arranged adjacent to each other in/on the component carrier.

Conventionally, one had to decide either in favor of high-accuracy signal transmission (i.e. smooth copper surfaces, thereby avoiding e.g. the skin-effect that causes signal quality to drop) or in favor of a robust design (i.e. rough copper surfaces, thereby improving adhesion between metal and dielectric material).

It has now been surprisingly found that a perfect compromise between signal transmission quality and a robust and stable design can be established in a straightforward manner: while the first metal traces with the rough surface promote the adhesion to dielectric component carrier material (thereby e.g. avoiding delamination), the second metal traces with the smooth surface enable a high reliability of high-frequency signal transmission. Since the metal traces are arranged adjacent to each other, both can be efficiently realized in one and the same component carrier.

The described advantageous component carrier may be manufactured using established component carrier processes, thereby enabling an implementation in existing production lines. For example, the surfaces of the second metal traces may be selectively protected by a specific protection layer while the surfaces of the first metal traces are roughened, e.g. by micro-etching (micro-etching may comprise chemical etching (e.g. flash etching) and/or physical etching (e.g. plasma etching).

According to an embodiment, the rough surface comprises a surface roughness (Ra) of more than 500 nm, in particular more than 700 nm. Additionally or alternatively, the smooth surface comprises a surface roughness (Ra) of less than 500 nm, in particular less than 300 nm, more in particular less than 100 nm.

The “roughness” of a surface quantifies the extent to which the surface deviates from its ideal form. Any deviations are usually analyzed in direction of the normal vector of the surface and are characterized by an amplitude, i.e. the height or length of the deviations in surface normal direction, and by a frequency, denoting the amount or number of deviations per surface area. Surface roughness correlates with friction between interacting rough surfaces, if they are moved relative to each other.

One of the most common roughness parameters is Ra, which may be the arithmetic average of the absolute values of surface deviations from a mean surface profile. The unit of the roughness parameter Ra is length and it is typically measured in micrometers or nanometers. The mean surface profile may be filtered from the raw surface profile, i.e. the measured surface profile, e.g. by eliminating a waviness component of surface deviations.

Roughness Ra may thus be calculated as

$$Ra = {\sum }_{m = 1 , ... , M} {\sum }_{n = 1 , ... , N} \vert z ( {x}_{m} , {y}_{n} ) - < z > \vert / MN$$

$$with$$

$$< \text{z>} = {\sum }_{m = 1 , ... , M} {\sum }_{n = 1 , ... , N} z ( {x}_{m} , {y}_{n} ) / MN .$$

Here, the sampling points (xₘ, yₙ) are equally spaced in directions x and y, which span the plane of the examined surface, and z is the direction normal to the examined surface. Thus, z(xₘ, yₙ) denotes the surface deviation from the mean surface profile in direction of the surface normal at sampling point (xₘ, yₙ). M and N determine the evaluation length in x-direction and in y-direction, respectively.

According to a further embodiment, the second metal trace comprises rough surface portions and smooth surface portions, in particular in an alternating manner. This may provide the advantage that a hybrid metal trace can be obtained that comprises portions with a rough surface and portions with a smooth surface. Depending on the function of the hybrid metal trace, the rough or the smooth surface portions may dominate. For example, if the hybrid metal trace is rather used for lower frequencies (in comparison to high frequencies), than the number of rough surfaces may be significantly higher than the number of smooth surfaces. In another example, where the hybrid metal trace may be applied rather for transmission of high frequencies, the number of smooth surfaces may be significantly higher.

According to a further embodiment, the HF signals comprise a frequency of at least 6 GHz, in particular at least 28 GHz. This may provide the advantage that signals in the high-frequency range may be transmitted (in particular via the second metal traces) in an accurate and reliable manner.

According to a further embodiment, the first metal trace and the second metal trace are embedded in a common encapsulation material (encapsulant). Thereby, both traces may be efficiently protected and eventually signal transmission quality is further improved. The first metal trace may hereby serve to establish a strong adhesion to the (dielectric) encapsulation material, while the second trace may reliably transport HF/high-speed signals. Additionally, the encapsulant may protect the metal traces from oxidation and/or corrosion, which may retrain the roughness of the metal traces (e.g. oxidation may increase the roughness).

According to a further embodiment, only the second metal trace is at least partially covered by a protection layer/material. This embodiment may directly reflect the manufacturing process, wherein the second metal trace surface is protected against surface roughening of the adjacent first metal trace. There are different options of how to configure the protection material. In an example, the protection material may be one of an elastic polymer coating, an ink, an adhesion promoter (e.g. a bond film), a peel-off film, a strip varnish. In an example, the protection material may comprise a barrier layer. Such a barrier layer may be silicon-based and may suppress electromagnetic interference as well as ion migration. Further, the barrier layer may increase the adhesion. This may provide the advantage that efficient protection and efficient removal (preferably without residues) is enabled. In another example, the protection material may be a (plated) metal, e.g. chromium. While in some embodiments, the protection material is removed from the second metal trace(s), in other embodiments, the protection material may be kept even during further encapsulation steps. In the latter case, both metal traces may be encapsulated together, whereby only the second metal trace comprises additionally the protection material.

According to a further embodiment, the component carrier further comprises a cavity in the stack, wherein the bottom and/or the sidewalls of the cavity are at least partially covered by the second metal trace. In this example, the cavity (e.g. formed between two electrically insulating layer structures) may be (at least partially) delimited by smooth surface second metal traces. The component carrier may comprise the rough surface first metal traces than outside of the cavity. An advantageous application of this architecture may be that the cavity (which may be filled by a suitable material) may be used as a wave guide. Herby, the smooth surfaces may improve the signal transmission, while the rough surfaces avoid delamination of the stack. Examples of this design are described with respect to FIGS. 8 and 9 below.

According to a further embodiment, the component carrier (in particular as described above) further comprises a resin layer structure, in particular a prepreg, arranged on top of the first metal trace. This may provide the advantage that adhesion between the (electrically insulating) layers can be improved. The rough surface may establish a robust adhesion. Additionally or alternatively, the component carrier comprises a non-resin layer structure, in particular a sinter paste, arranged on top of the second metal trace. Such a non-resin layer structure may adhere well to a smooth surface, thereby providing stability. In an example, the sinter paste may be located in the above-identified cavity, in particular sandwiched between the two second metal traces.

According to a further embodiment, the component carrier further comprises an adhesion promotor arranged between the non-resin layer structure and the second metal trace. Thereby, the adhesion (e.g. of sinter paste) to the smooth surface may be promoted. The adhesion promoter may be configured as a layer and/or as separated islands. In an example, the adhesion promoter comprises an electrically insulating material with enhanced adhesion properties, e.g. polyimide (PI).

According to a further embodiment, the component carrier further comprises a further second metal trace arranged on top of the non-resin layer structure and/or on top of the cavity (in particular so that the non-resin layer structure or the cavity functions as a waveguide). As has already been mentioned above, an empty or a filled cavity between two smooth surface second metal traces may be applied as a wave guide in a straightforward manner. The smooth surface on top and on bottom of the wave guide may enable high-quality signal transmission. In an example, further sidewalls of the cavity may also comprise a second metal traces with respective smooth surfaces.

According to a further embodiment, the second metal trace comprises the smooth surface at the top portion, while at least one sidewall portion comprises a rough surface. In an example, it may not be necessary that the whole surface of the second metal trace is smooth.

According to a further embodiment, the second metal trace comprises the smooth surface at at least one sidewall, while the top portion comprise a rough surface. Instead, only the top portion may be smooth or only one or more sidewall portion may be smooth. These differences may be advantageous for specific embodiments. For example, a combination of signal transmission quality, stability and cost-efficiency may be achieved in this manner. A smooth top portion surface or a smooth sidewall portion surface may be achieved by selective processes, for example including LDI (laser direct image). LDI may only use a computer-controlled, highly focused, electromagnetic radiation, e.g. a light (beam) created by a laser, to directly define a circuit pattern (metal traces) onto the component carrier. The component carrier surface may be covered with a photoresist. Then, the laser creates the future metal traces on the photoresist. Photoresist not exposed to the laser is subsequently removed by etching.

According to an exemplary example, the standard LDI process may be performed as follows: i) a metal surface is at least partially, preferably totally, covered by a PID-material in a lamination step (temporarily adding a new layer to the stack); ii) at least one area of the PID covered stack is exposed by electromagnetic radiation (in particular UV light); iii) in an additive process, the UV exposed portions of the PID material get soluble and will be removed during the development step; In a subtractive process, the non-exposed portion will be removed; iv) at the portion where the PID layer was removed, metal is removed by an etching process (chemical or physical) to create defined metal portions (traces) on top of the stack (which are still covered by the PID material which remained after development step); and v) said remaining PID material is removed by a so-called stripping process.

Afterwards other process steps may be applied (e.g. surface finish, lamination and repeating LDI, etc.)

Additionally, and/or alternatively every other feasible process may be used to create said geometric features.

According to a further embodiment, the component carrier comprises a peripheral portion and a central portion, and the surface roughness of first metal traces at the peripheral portion of the component carrier is larger than the surface roughness of first metal traces at the central portion of the component carrier. In a further embodiment, the number of first metal traces in the peripheral portion is larger than in the central region. Hereby, the number of second metal traces in the peripheral portion may be smaller than in the central region. This architecture may provide the advantage that adhesion between metal trace and dielectric material is especially promoted in the peripheral portion, where a strong adhesion may be more important for the overall stability of the component carrier in comparison to the central portion.

According to a further embodiment, at least one first metal trace is larger (e.g. regarding larger area of the cross section, wider, higher, larger volume) than the adjacent second metal trace. In particular, said at least one first metal trace is configured as a non-functional electrically conductive (dummy trace). The larger metal trace may be applied for adhesion-promotion only, whereby a larger surface area may also further improve said adhesion. Such an enlarged first metal trace may be non-functional with respect to HF/high-speed signal transmission, or not be used for signal transmission at all. Additionally or alternatively, said enlarged first metal trace may be used for heat transport (heat dissipation).

According to a further embodiment, at least one first metal trace is a dummy trace that is not used for (HF) signal transmission. In particular, at least one first metal trace is not used to conduct electricity at all. In this embodiment, the first metal trace(s) serve(s) as an anchor between a rough metal surface and dielectric (resin) material.

According to a further embodiment, forming the first metal trace comprises micro-etching the first metal trace surface to yield a rough surface. Thus, an established process may be directly applied to efficiently roughen the first surface. Additionally or alternatively, electrochemical metal striping may be performed. In an example, micro-etching comprises chemical and/or physical etching e.g. plasma etching.

According to a further embodiment, forming the second metal trace comprises protecting the smooth surface of the second metal trace with a protection structure, in particular during micro-etching of the first metal trace. The protection structure may be a protection material and/or protection layer as described above.

According to a further embodiment, protecting further comprises covering the first metal trace with a first dielectric material before applying the protection structure. The first dielectric material may be a photo-imagable dielectric (PID) layer structure. In an embodiment, the first dielectric material protects the first metal traces, while the second metal traces are covered by the protection structure, e.g. by plating.

In this manner, the second metal traces may be covered with a further layer of metal, in particular copper. Additionally, or alternatively, other metals like nickel, gold, silver, palladium, chromium, titanium, etc. (generally all metals that withstand the roughening process would be feasible to create a barrier layer) may be used. Covering the second metal traces with other metal may have the advantage to prevent oxidation or corrosion reactions.

According to a further embodiment, an increased electric conductivity may significantly improve data transmission and reduce signal losses, thereby improving HF and high-speed applications. Thus, besides decreasing the surface roughness and/or protecting metal traces from oxidation, the metal trace may be further tuned as follows: applying a protection/barrier layer for reduced electromagnetic interference, and/or applying an electrically conductive (e.g. graphene) coating to increase the conductivity for improving signal transmission.

According to a further embodiment, the method further comprises: i) providing a plurality of adjacent metal traces, and ii) filling space between the metal traces with a second dielectric material (e.g. a PID material). In particular so that sidewalls of the metal traces are free from the second dielectric material.

In a specific example, the method further comprises filling the gaps with material of the protection structure. Thus, providing spaces may enable the second metal traces to be covered completely (also the sidewalls) with the protection structure. The protection layer may be provided as a metallic layer, e.g. by plating (barrier plating) or sputtering. Besides copper, other metals such as nickel, gold, silver, palladium, chromium, titanium, etc. may be used.

According to a further embodiment, forming the second metal trace comprises: forming a metal trace with a rough surface (in particular in the same process as forming the first metal trace), and subsequently smoothing the rough surface to yield the second metal trace with the smooth surface, e.g. by applying electromagnetic waves such as laser light and/or thermal treatment. In this embodiment, at least one second metal trace is formed from a first metal trace, in other words, a smooth surface is formed out of a rough surface.

According to a further embodiment, the method further comprises: grinding, in particular using laser energy on the rough surface and/or plating the rough surface. Smoothing a surface may for example be achieved by grinding, which may be done mechanically and/or by selective laser ablation (see e.g. FIG. 6). Furthermore, smoothing a surface may comprise plating additional copper of a rough surface.

According to a further embodiment, the method further comprises embedding, in particular encapsulating, the first metal trace and the second metal trace in a common encapsulation material. Thereby, stability and eventually signal transmission quality may be enhanced.

According to a further embodiment, the method further comprises: forming a resin layer structure (in particular a prepreg) on top of the first metal trace, and/or forming a non-resin layer structure (in particular a sinter paste) on top of the second metal trace and/or forming a cavity on top of the second metal trace. Thereby, a reliable wave guide may be provided in a component carrier in an efficient manner.

According to a specific example, forming a resin layer structure (in particular a prepreg) on top of the first metal trace, and/or forming a non-resin layer structure, in particular a sinter paste, on top of the second metal trace (or any metal-based structure, such as a via pad or an copper inlay) allows for selectively increasing the surface roughness at positions where an interconnection is intended to be established. Such an interconnection could for instance be an interface between two layer stacks. These interconnections may be weak points and prone for undergoing delamination when stressed. Using a sinter-paste to increase the surface roughness may have two main advantages: on the one hand an interconnection between at least two layers with improved adhesion is obtained; while on the other hand such interconnections are electrically conductive and may be integrated as a barrier for electromagnetic waves. Such a method could for instance be applied on a stack comprising a cavity. The surface of such a stack can be selectively covered with a sinter-paste, preferably at the area where an interconnection between two stacks should be established. After engaging two stacks with each other and thereby sealing the cavity with the bottom of another stack, a mechanically and electrically reliable interconnection can be manufactured. The resulting, sealed cavity, e.g. a waveguide, can for instance be used as a signal path between active circuits and components as well as passive components like filters or an antenna.

According to a further embodiment, the method further comprises: providing a further second metal trace on top of the non-resin layer structure and/or the cavity, to thereby provide a waveguide structure.

According to a further embodiment, the method further comprises: configuring the component carrier, so that high-frequency, HF, signals can be guided through the second metal trace, wherein the HF signals comprise a frequency of at least 1 GHz, in particular 6 GHz, more in particular at least 28 GHz. As described above, a low surface roughness may reduce the skin effect and thereby provide an increased signal transmission quality. In an example, only the second metal trace(s) is/are applied for said high-frequency signal transmissions.

According to a further embodiment, at least one electrically non-functional (rough-surface) metal structure (which has no potential applied, i.e. no electric current will flow) is applied. This may provide the advantage that the surface roughness and hence, the adhesion may be improved. Further, an electromagnetic radiation shielding may be applied in this manner. Such “electrically non-functional” structures are usually implemented for shielding purposes, or for thermal management, e.g. vias and through holes (so-called via fence or thermal vias), copper-filled slots, copper coated components, copper planes, and other structures intended for shielding or heat spreading, where no potential is applied.

According to a further embodiment, at least one metal trace is manufactured by an additive or a subtractive manufacturing process.

Depending on the different manufacturing processes different shapes of the metal traces are produced.

According to a further embodiment, at least one metal trace comprises an (essentially) vertical/straight sidewall, in particular wherein the metal trace comprises a cuboidal or cylindrical shape. According to a further embodiment, at least one metal trace comprises a tapering sidewall, in particular wherein the metal trace comprises a trapezoidal shape.

According to a further embodiment, at least one metal trace comprises a shape from the group which consists of rectangular, trapezoidal, circular, frustoconical, cuboidal.

According to a further embodiment, the protection layer comprises a smooth surface. In arrangements where the protection layer may become part of the signal carrying structure (e.g. if gold is used to create the protection layer) it may be advantageous to provide a smooth surface as well. In arrangement with a temporary protection layer (e.g. photoresist) this measure may not be necessary.

According to a further embodiment, the protection layer is at least partially located in the (further) cavity (not shown in FIGS. 8 and 9). In a specific example, the protection layer/material fills the (further) cavity.

According to a further embodiment, the opening of the (further) cavity is closed flush by the protection layer (see FIGS. 8 and 9).

In an embodiment, the stack comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier is shaped as a plate. This contributes to the compact design, wherein the component carrier nevertheless provides a large basis for mounting components thereon. Furthermore, in particular a naked die, as an example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise for example resin and/or glass fibers, so-called prepreg or FR4 material, PID, or ABF. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres, or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high-frequency applications, high-frequency materials such as polytetrafluoroethylene, liquid crystal polymer and/or cyanate ester resins, may be preferred. Besides these polymers, low-temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular coated with supra-conductive material or conductive polymers, such as graphene or poly(3,4-ethylenedioxythiophene) (PEDOT), respectively.

At least one further component may be embedded in and/or surface mounted on the stack. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer, or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

### BRIEF DESCRIPTION OF THE DRAWINGS

The aspects defined above and further aspects of the disclosure are apparent from the examples of embodiment to be described hereinafter and are explained with reference to these examples of embodiment.

FIG. 1a and FIG. 1b show first metal traces and second metal traces adjacent to each other according to exemplary embodiments of the disclosure.

FIG. 2a, FIG. 2b, FIG. 2c, FIG. 2d, FIG. 2e, FIG. 2f show a first component carrier manufacturing process according to an exemplary embodiment of the disclosure.

FIG. 3a, FIG. 3b, FIG. 3c, FIG. 3d, FIG. 3e show a second component carrier manufacturing process according to an exemplary embodiment of the disclosure.

FIG. 4a, FIG. 4b, FIG. 4c, FIG. 4d, FIG. 4e, FIG. 4f show a third component carrier manufacturing process according to an exemplary embodiment of the disclosure.

FIG. 5a, FIG. 5b, FIG. 5c, FIG. 5d show a fourth component carrier manufacturing process according to an exemplary embodiment of the disclosure.

FIG. 6a, FIG. 6b, FIG. 6c, FIG. 6d show a fifth component carrier manufacturing process according to an exemplary embodiment of the disclosure.

FIG. 7a, FIG. 7b, FIG. 7c, FIG. 7d, FIG. 7e, FIG. 7f show a sixth component carrier manufacturing process according to an exemplary embodiment of the disclosure.

FIG. 8a, FIG. 8b, FIG. 8c, FIG. 8d show a seventh component carrier manufacturing process that involves forming a wave guide according to an exemplary embodiment of the invention.

FIG. 9a, FIG. 9b, FIG. 9c, FIG. 9d show an eighth component carrier manufacturing process that involves forming a wave guide according to a further exemplary embodiment of the disclosure.

FIG. 10 shows second metal traces only partially with smooth surfaces according to an exemplary embodiment of the disclosure.

FIG. 11 shows a component carrier with an enlarged first metal trace according to an exemplary embodiment of the disclosure.

FIG. 12 shows a component carrier having first metal traces with different roughness according to an exemplary embodiment of the disclosure.

### DETAILED DESCRIPTION OF ILLUSTRATED EMBODIMENTS

The illustrations in the drawings are schematically presented. In different drawings, similar or identical elements are provided with the same reference signs.

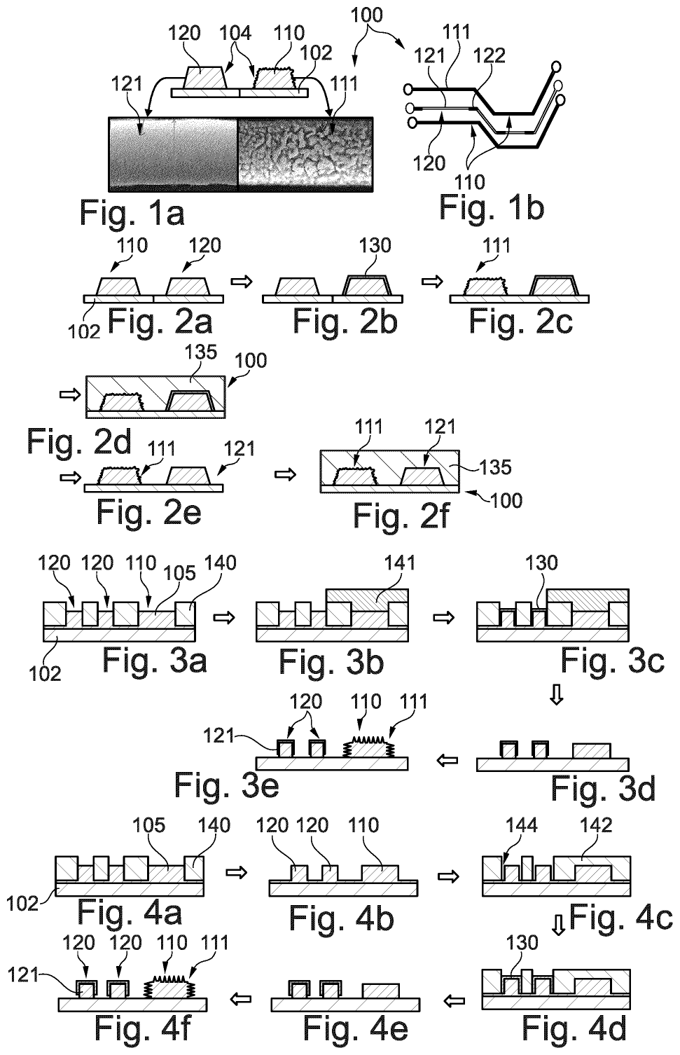

FIG. 1a shows component carrier 100 and metal traces 110, 120 manufactured according to an exemplary embodiment of the disclosure. A first metal trace 110 comprises a rough surface 111 and a second metal trace 120, arranged adjacent to the first metal trace 110, comprises a smooth surface 121.

The metal traces 110, 120 are electrically conductive structures 104 of the component carrier stack that further comprises an electrically insulating layer structure 102, which serves as a support structure for the metal traces 110, 120.

FIG. 1b shows two first metal traces 110 with rough surfaces 111.

In between, there is located a metal trace that comprises portions with smooth surfaces 121 and with rough surfaces 122, alternating with each other. The portions with rough surfaces 122 can be seen as first metal traces 110. The traces 110, 120 can comprise pads for an electrical connection, e.g. at the endpoints of the trace. In other words, especially for long traces, such anchor points with enhanced adhesion properties can be formed.

FIGS. 2a to 2f show a first component carrier manufacturing process according to an exemplary embodiment of the disclosure.

FIG. 2a: a dielectric support structure 102 with a first metal trace 110 and a second metal trace 120, adjacent to each other, is provided. Both metal traces 110, 120 comprise a smooth surface.

FIG. 2b: the second metal trace 120 is coated by a protection layer/material 130. Said protection layer 130 can comprise for example one of an elastic polymer coating, an ink, an adhesion promoter (e.g. a bond film), a peel-off film, a strip varnish, a barrier layer, a graphene layer. However, the protection material 130 can also be a (plated/sputtered) metal, e.g. chromium.

FIG. 2c: a component carrier manufacturing step is performed selectively for the first metal trace 110, while the second metal trace 120 is protected by the protection layer 130. The manufacturing step comprises surface roughening (e.g. by micro-etching) the first metal trace surface to provide the rough surface 111.

FIG. 2d: alternative 1: both metal traces 110, 120 are embedded in a common encapsulating (insulating) material 135. Hereby, the second metal trace 120 is still protected by the protection (barrier) layer 130.

FIG. 2e: alternative 2: the protection layer 130 is removed (e.g. by a (hot) pressurized fluid stream, preferably without leaving residues).

FIG. 2f: also alternative 2, both metal traces 110, 120 are embedded in a common encapsulating material 135, whereby the protection layer 130 had been removed from the second metal trace 120. Due to the protection layer(s) 130, the surface for the second metal trace 120 remains with its initial lower roughness.

FIGS. 3a to 3e show a second component carrier manufacturing process according to an exemplary embodiment of the disclosure.

FIG. 3a: a plurality of first metal trace 110 preforms and a plurality of second metal traces 120 are provided in the form of a patterned metal layer structure 105 on a common electrically insulating layer structure 102 support structure. A dielectric material 140 is provided in between the traces.

FIG. 3b: a first dielectric material 141 is applied on the first metal trace 110 preform as a cover.

FIG. 3c: a protection layer/material 130 is provided on the second metal traces 120 as a protection (e.g. by plating). In this example, the protection layer 130 comprises also a smooth surface.

FIG. 3d: the first dielectric material 141 (e.g. a PID material) and the dielectric material 140 are removed (e.g. by a photolithography process), thereby exposing the first metal trace 110 preforms. After an etching process (to separate the metal traces), there may be an under etch present (see in the Figure). This under-etch may also be seen as a structural feature in the final product. As a consequence, the protection layer 130 is not in direct (physical) contact with the insulating layer structure 102.

FIG. 3e: a surface roughening process is performed, whereby the unprotected first metal trace 110 preforms are surface roughened, thereby providing the first metal traces 110. The second metal traces 120 are instead still protected by the protection material 130.

FIGS. 4a to 4f show a third component carrier manufacturing process according to an exemplary embodiment of the invention.

FIG. 4a: a plurality of first metal trace 110 preforms and a plurality of second metal traces 120 are provided in the form of a patterned metal layer structure 105 on a common electrically insulating layer structure 102 support structure. A dielectric material 140 is provided in between the traces.

FIG. 4b: the dielectric material 140 is removed.

FIG. 4c: a second dielectric material 142 is provided between the metal traces 110, 120 in such a manner that there are gaps 144 remaining between the second dielectric material 142 and the metal traces 110, 120. In particular, the second dielectric material 142 is applied so that the first metal trace 110 preforms are completely covered.

FIG. 4d: the protection material 130 is applied on the second metal traces 120 so that the top as well as the sidewalls are covered. The latter is enabled by the presence of the gaps 144. The application of the protection material 140 can be done e.g. by selective plating.

FIG. 4e: the second dielectric material 142 is removed, thereby exposing the first metal trace 110 preforms completely, while the second metal traces 120 are still protected by the protection material 130. By a separate etching step, the seed metal layer will be removed which will create a certain degree of undercut (seed layer thickness for example ≤0.7 um). After an etching process (to separate the metal traces), there may be an under etch (undercut) present (see in the Figure). This under-etch may also be seen as a structural feature in the final product. As a consequence, the protection layer 130 is not in direct (physical) contact with the insulating layer structure 102.

FIG. 4f: a surface roughening process is performed, whereby the unprotected first metal trace 110 preforms are surface roughened, thereby providing the first metal traces 110. The second metal traces 120 are instead still protected by the protection material 130, so that the surfaces remain smooth.

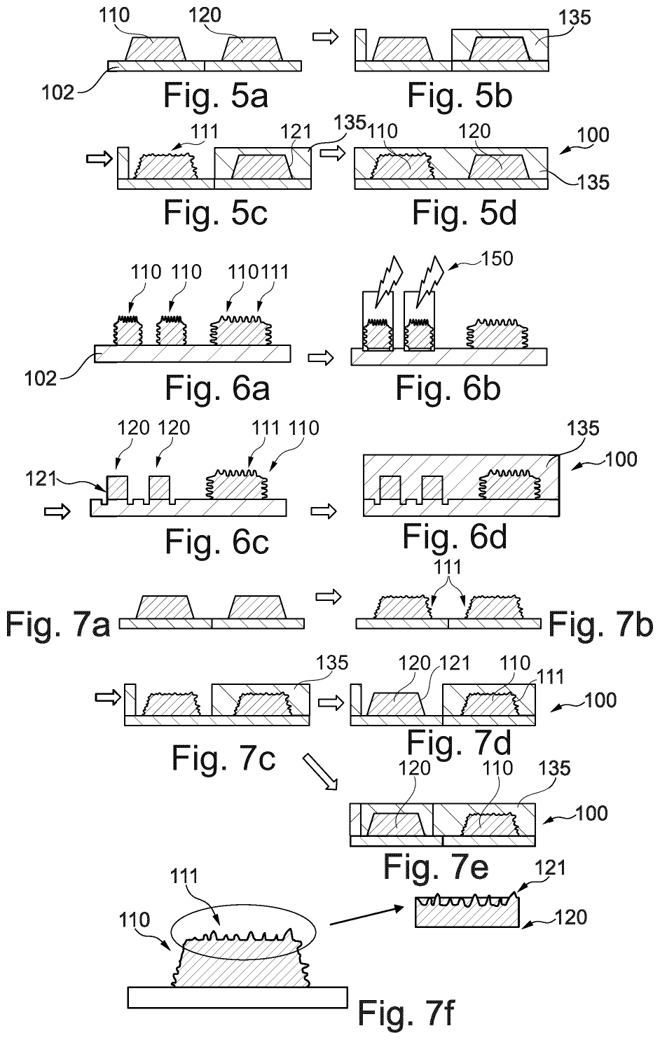

FIGS. 5a to 5d show a fourth component carrier manufacturing process according to an exemplary embodiment of the disclosure.

FIG. 5a: a first metal trace 110 and a second metal trace 120 are provided on a common electrically insulating layer structure 102 support structure.

FIG. 5b: only the second metal trace 120 is encapsulated in an encapsulating material (e.g. a mold material like a resin) 135.

FIG. 5c: a surface roughening process is performed, whereby the unprotected first metal trace 110 is surface roughened, thereby providing the rough surface 111. The second metal trace 120 is protected by the encapsulating material 135, so that the surface remains smooth 121.

FIG. 5d: the first metal trace 110 with the rough surface 111 is also embedded in the encapsulating material 135 (the same material as for FIG. 5b or another material), so that both metal traces 110, 120 are now embedded in a common encapsulant 135.

FIGS. 6a to 6d show a fifth component carrier manufacturing process according to an exemplary embodiment of the disclosure.

FIG. 6a: there are formed a plurality of first metal traces 110 with respective rough surfaces 111 on a common electrically insulating layer structure 102.

FIG. 6b: laser energy 150 is applied to a part of the first metal traces 110.

FIG. 6c: after the laser ablation 150, the rough surfaces of the part of the first metal traces 110 have been changed into smooth surfaces 121, thereby turning said first metal traces 110 into second metal traces 120 with smooth surfaces 121. By using the laser ablation 150, portions of the electrically insulating layer structure 102 are removed, in particular, directly around the second metal traces 120. This manufacturing step may be reflected as a structural feature in the final product.

FIG. 6d: the first metal traces 110 and the second metal traces 120 are embedded in a common encapsulant 135.

FIGS. 7a to 7f show a sixth component carrier manufacturing process according to an exemplary embodiment of the disclosure.

FIG. 7a: there are formed two metal traces on a common electrically insulating layer structure 102.

FIG. 7b: the surfaces of both metal traces are roughened to provide the first metal traces 110 with rough surfaces 111.

FIG. 7c: only the right first metal trace 110 is encapsulated in an encapsulating material 135.

FIG. 7d: the surface of the left first metal trace 110 is smoothed (e.g. by laser ablation or additional plating or grinding), so that said first metal trace 110 is turned into a second metal trace 120 with a smooth surface 121. The right first metal trace 110 is instead protected by the encapsulant 135.

FIG. 7e: both metal traces 110, 120 are embedded in a common encapsulant 135 (which may be the same encapsulant as for FIG. 7c or a different material).

FIG. 7f shows an example, where a rough surface 111 of a first metal trace 110 is plated with metal material (e.g. copper), to thereby smoothen the surface. Afterwards, the surface is less rough, however, not as smooth as in the case of the second metal trace 120.

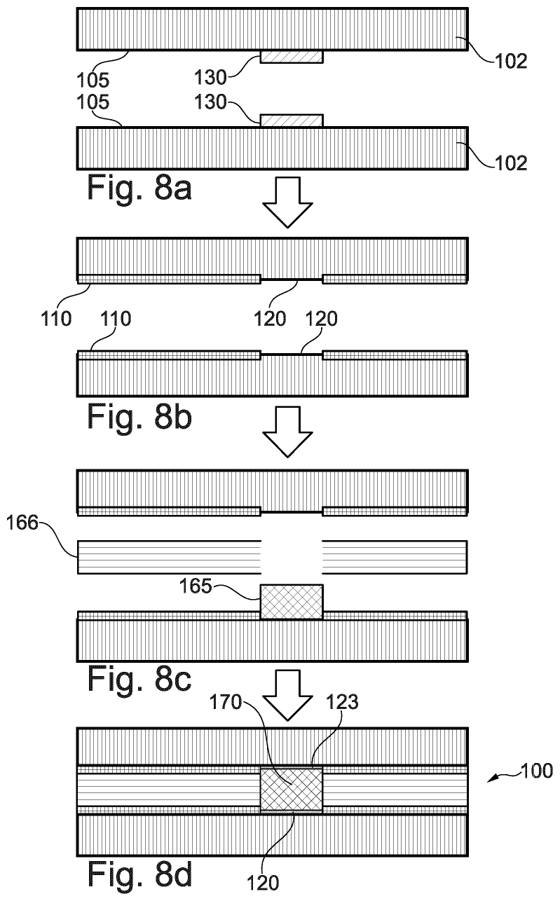

FIGS. 8a to 8d show a seventh component carrier manufacturing process that involves forming a wave guide according to an exemplary embodiment of the disclosure.

FIG. 8a: there are provided two component carrier (preforms) in the form of an electrically insulating layer structure 102 covered by an electrically conductive layer 105, respectively (e.g. a copper-clad-laminate). The first support structure comprises a protection layer 130 at the bottom main surface and the second support structure comprises a further protection layer 130 at the top main surface. The term “main surface” may in this context refer to a surface that is parallel to the directions of main extension (x, y) of the component carrier and perpendicular to the stacking direction (z). The protection layers 130 respectively protect a portion not to be processed.

FIG. 8b: portions not protected by the protection layer 130 are portions to be processed. The surface of these portions to be processed is roughened 111 selectively, e.g. by micro-etching, thereby providing first metal traces 110. Afterwards, the protection layers 130 are removed, leaving smooth surface 121 on the second metal traces 120 and/or the further second metal traces 123 behind.

FIG. 8c: a resin layer structure 166 (in particular a prepreg) is arranged between the first metal traces 110 of the first support structure and the second support structure, respectively. In an example, the second metal traces 120 are not in direct contact with the resin material 166. Further, a non-resin layer structure 165 (in particular a sinter paste) is arranged between the second metal traces 120 of the first support structure and the second support structure, respectively. While the resin layer structure 166 adheres well to the rough surfaces 111, the sinter paste is connected to the smooth surfaces 121 in a robust manner. An adhesion promoter (e.g. PI) can be arranged between the non-resin layer structure 165 and the second metal trace 120 (not shown).

FIG. 8d: the non-resin layer structure 165 is embedded between the second metal trace 120 and a further second metal trace 123. The non-resin layer structure 165 can function as a waveguide 170.

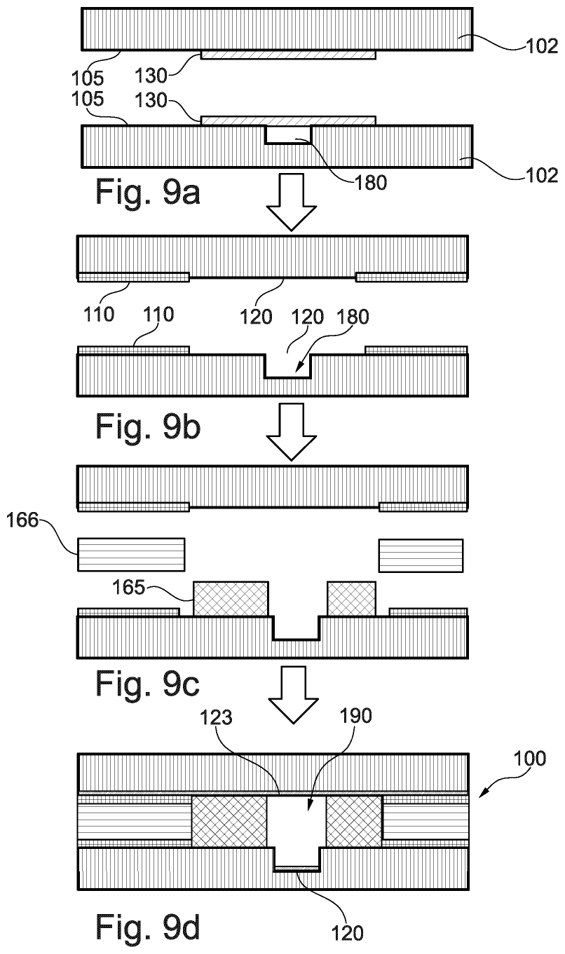

FIGS. 9a to 9d show an eighth component carrier manufacturing process that involves forming a wave guide according to an exemplary embodiment of the disclosure.

FIG. 9a: there are provided two component carrier (preforms) in the form of an electrically insulating layer structure 102 covered by an electrically conductive layer 105, respectively (e.g. a copper-clad-laminate). The first support structure comprises a protection layer 130 at the bottom main surface and the second support structure comprises a further protection layer 130 at the top main surface. The protection layers 130 respectively protect a portion not to be processed. Furthermore, a cavity 180 is formed in the lower support structure below the respective protection layer 130. The bottom and the sidewalls of the cavity 180 are covered by smooth surface second metal trace 120 material.

FIG. 9b: portions not protected by the protection layer 130 are portions to be processed. The surface of these portions to be processed is roughened 111 selectively, e.g. by micro-etching, thereby providing first metal traces 110. Afterwards, the protection layers 130 are removed, leaving smooth surface 121 on second metal traces 120 and/or further second metal traces 123 behind. Furthermore, the cavity 180 is now exposed.

FIG. 9c: a resin layer structure 166 (in particular a prepreg) is arranged between the first metal traces 110 of the first support structure and the second support structure, respectively. Further, a non-resin layer structure 165 (in particular a sinter paste) is arranged between the second metal traces 120 of the first support structure and the second support structure, respectively (there is a cut-out provided). While the resin layer structure 166 adheres well to the rough surfaces 111, the sinter paste is connected to the smooth surfaces 121 in a robust manner. Hereby, there is no non-resin layer structure 165 arranged in the cavity 180 and not extending in the cavity 180 in stack thickness direction. Additionally, the edges of the cavity 180 are free of the non-resin layer structure 165.

FIG. 9d: the non-resin layer structure 165 is preferably at least partially embedded between the second metal trace 120 and a further second metal trace 123 (cavity 190 is not filled up). Furthermore, the cavity 180 is now enlarged and located between the second metal trace 120 and the further second metal trace 123. In this example, the further cavity 190 between the second metal traces 120, 123 functions as a wave guide. In this example, there is a step between the cavity in the lower support structure and the non-resin layer structure 165. Additionally and/or alternatively, the insulating layer structure 102 and the non-resin layer structure 165 can be flush. This may have an advantage in that the function as a wave guide will be enhanced.

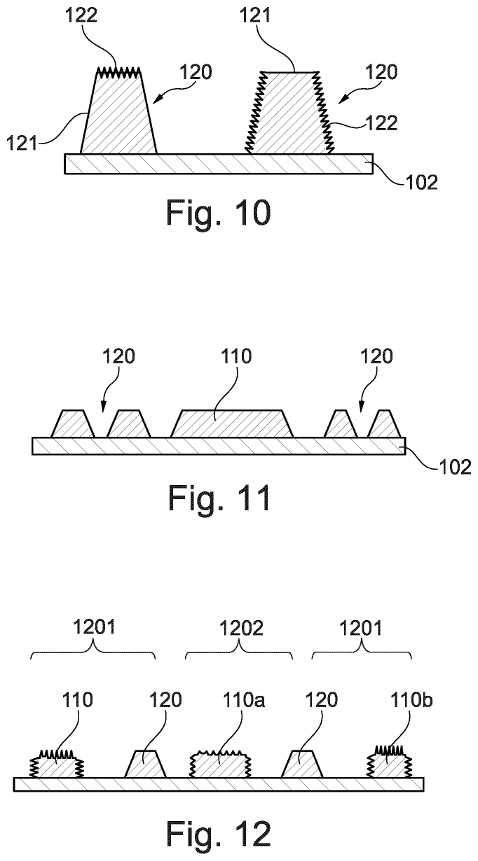

FIG. 10 shows second metal traces 120 that comprise only partially smooth surfaces 121 according to an exemplary embodiment of the disclosure. The second metal trace 120 at the left side comprises the smooth surface 121 at the sidewalls (portion), while, at the top portion, it comprises a rough surface 122. The second metal trace 120 at the right side in turn comprises the smooth surface 121 at the top portion, while it comprises at the sidewalls a rough surface 122. These structures may be provided by LDI (laser direct image) technology.

FIG. 11 shows a component carrier 100 with an enlarged first metal trace 110 arranged between a plurality of second metal traces 120 according to an exemplary embodiment of the disclosure. The first metal trace 110 is larger in width than the adjacent second metal traces 120. In this example, the enlarged first metal trace 110 is configured in a non-functional electrically conductive manner and serves rather for stability of the component carrier 100. Alternatively, the enlarged first metal trace 110 comprises a function of transferring heat (e.g. heat sink). In the alternative arrangement the enlarged first metal trace 110 can transmit current (e.g. is electrically functional), as well as provide a large anchor area for improving adhesion.

FIG. 12 shows a component carrier having first metal traces 110 with different roughness according to an exemplary embodiment of the disclosure. The component carrier 100 comprises two peripheral portions 1201 arranged at the edges of the component carrier 100 and a central portion 1202 in between the peripheral portions 1201. The surface roughness of first metal traces 110b at the peripheral portion 1201 of the component carrier 100 is larger than the surface roughness of first metal traces 110a at the central portion 1202 of the component carrier 100. Thereby, adhesion can be especially promoted in the peripheral region, where stability and robustness can be crucial. In turn, first metal traces 110a with a lower roughness at the center can be used as a compromise between stable design and accuracy of signal transmission.

### REFERENCE SIGNS

100 Component carrier
102 Electrically insulating layer structure, support structure
104 Electrically conductive layer structure, metal trace
105 Metal layer
110 First metal trace
111 Rough surface
120 Second metal trace
121 Smooth surface
122 Rough surface second metal trace
123 Further second metal trace
130 Protection material/layer/structure
135 Encapsulating material
140 Dielectric material
141 First dielectric material
142 Second dielectric material
144 Gaps
150 Laser energy
165 Sinter paste
166 Prepreg layer
170 Closed waveguide
180 Cavity
190 Further cavity, open waveguide
1201 Peripheral region
1202 Central region

1. A component carrier comprising:
a stack comprising at least one electrically insulating layer structure and at least one electrically conductive layer structure;
a first metal trace comprising a rough surface; and
a second metal trace arranged adjacent to the first metal trace, comprising a smooth surface;
wherein the component carrier is configured to guide at least one of high-frequency, HF, signals and high-speed signals through the second metal trace.

2. The component carrier according to claim 1, wherein the rough surface comprises a surface roughness of more than 500 nm; and/or
wherein the smooth surface comprises a surface roughness of less than 500 nm.

3. The component carrier according to claim 1,
wherein the second metal trace comprises rough surface portions and smooth surface portions in an alternating manner.

4. The component carrier according to claim 1,
wherein the HF signals comprise a frequency of at least 1 GHz.

5. The component carrier according to claim 1,
wherein the first metal trace and the second metal trace are embedded in a common encapsulation material.

6. The component carrier according to claim 1,
wherein only the second metal trace is at least partially covered by a protection layer.

7. The component carrier according to claim 1, further comprising:
a cavity in the stack, wherein the bottom and/or the sidewalls of the cavity are at least partially covered by the second metal trace.

8. The component carrier according to claim 1, further comprising:
a resin layer structure arranged on top of the first metal trace, and/or
a non-resin layer structure arranged on top of the second metal trace.

9. The component carrier according to claim 8, comprising at least one of the following features:
further comprising: an adhesion promotor arranged between the non-resin layer structure and the second metal trace, wherein the adhesion promoter comprises polyimide, PI;
a further second metal trace arranged on top of the non-resin layer structure and/or on top of the cavity, such that the non-resin layer structure or the cavity functions as a waveguide.

10. (canceled)

11. The component carrier according to claim 1, comprising at least one of the following features:
wherein the second metal trace comprises the smooth surface at the top portion, while at least one sidewall portion comprises a rough surface; and/or
wherein the second metal trace comprises the smooth surface at at least one sidewall, while the top portion comprise a rough surface;
wherein the component carrier comprises a peripheral portion and a central portion, and wherein the surface roughness of first metal traces at the peripheral portion of the component carrier is larger than the surface roughness of first metal traces at the central portion of the component carrier;
wherein at least one first metal trace is larger than the adjacent second metal trace, wherein said at least one first metal trace is configured as a non-functional electrically conductive.

12.-13. (canceled)

14. A method of manufacturing a component carrier, the method comprising:
forming a stack comprising at least one electrically insulating layer structure and at least one electrically conductive layer structure;
forming a first metal trace with a rough surface;
forming a second metal trace, adjacent to the first metal trace, with a smooth surface; and
configuring the component carrier, so that at least one of high-frequency, HF, signals and high-speed signals can be guided through the second metal trace.

15. The method according to claim 14, wherein forming the first metal trace comprises:
micro-etching the first metal trace surface to yield a rough surface.

16. The method according to claim 14, wherein forming the second metal trace comprises:
protecting the smooth surface of the second metal trace with a protection material in when micro-etching the first metal trace;
wherein protecting further comprises:
covering the first metal trace with a first dielectric material before applying the protection material.

17. (canceled)

18. The method according to claim 1, further comprising:
providing a plurality of adjacent metal traces; and
filling gaps between the metal traces with a second dielectric material,
such that sidewalls of the metal traces are free from the second dielectric material; and
filling the gaps with the protection material.

19. The method according to claim 1, wherein forming the second metal trace comprises:
forming a metal trace with a rough surface in the same process as forming the first metal trace, and subsequently
smoothing the rough surface to yield the second metal trace with the smooth surface.

20. The method according to claim 19, wherein smoothing further comprises:
grinding the rough surface, and/or
plating the rough surface.

21. The method according to claim 14, further comprising:
embedding the first metal trace and the second metal trace in a common encapsulation material.

22. The method according to claim 14, further comprising:
forming a resin layer structure on top of the first metal trace; and/or
forming a non-resin layer structure on top of the second metal trace and/or forming a cavity on top of the second metal trace.

23. The method according to claim 22, further comprising:
providing a further second metal trace on top of the non-resin layer structure and/or the cavity, to thereby provide a waveguide structure.

24. A method, comprising:
providing a component carrier arranged with adjacent electrically conductive traces, wherein at least a first trace has a relatively smoother surface than a second trace; and
coupling a signal with a frequency of at least 6 GHz to the adjacent electrically conductive traces.
